(19) United States
(12) Patent Application Publication
(10) Pub. No.: US 2019/0344241 A1
(43) Pub. Date: Nov. 14, 2019

(54) METHOD FOR PRODUCING NUCLEIC ACID ARRAY AND DEVICE FOR PRODUCING NUCLEIC ACID ARRAY

(71) Applicant: Nikon Corporation, Tokyo (JP)

(72) Inventor: Yusuke KAWAKAMI, Yokohama-shi (JP)

(21) Appl. No.: 16/507,850

(22) Filed: Jul. 10, 2019

Related U.S. Application Data
(63) Continuation of application No. PCT/JP2018/000290, filed on Jan. 10, 2018.

(30) Foreign Application Priority Data
Jan. 12, 2017 (JP) 2017-003309

(51) Int. Cl. B01J 19/00

(52) U.S. Cl. CPC B01J 19/0046; B01J 2219/00736; G03F 7/162; B01J 2219/00626; B01J 2219/00596

(57) ABSTRACT

A method for producing a nucleic acid array which includes: a step of forming a resist film using a positive resist composition containing a photo acid generator for generating an acid as a result of being exposed to light on a solid phase which has a molecule immobilized thereon and having functional groups protected by an acid-decomposable protective group; a step of exposing a desired position of the resist film to light; a step of developing the resist film which has been subjected to development using a developing liquid; and a step of bringing the solid phase including the resist film which has been subjected to development into contact with a nucleotide derivative having an acid-decomposable protective group is provided.

### CROSS-REFERENCE TO RELATED APPLICATION

This is a Continuation Application of International Application No. PCT/JP2018/000290 filed on Jan. 10, 2018, which claims priority on Japanese Patent Application No. 2017-003309, filed on Jan. 12, 2017. The contents of the aforementioned applications are incorporated herein by reference.

### BACKGROUND

### Field of the Invention

The present invention relates to a method for producing a nucleic acid array and a device for producing a nucleic acid array.

### Background

There are two methods for preparing DNA micro-arrays, i.e., an Affymetrix type developed by Affymetrix and a Stanford type developed at Stanford University. The Affymetrix type is a method of synthesizing DNA above a substrate through a photolithographic process using a photosensitive base. On the other hand, the Stanford type is a method of spotting DNA above a substrate through robot printing technology.

According to the Affymetrix type, it is possible to produce a more highly integrated micro-array. However, according to J. Am. Chem. Soc., 1997, 119 (22), 5081 to 5090, a photosensitive base for patterning is special and it cannot be said that the light response associated with a throughput is sufficient in view of mass productivity.

### SUMMARY

An embodiment according to the present invention is a method for producing a nucleic acid array which includes: (a) a step of forming a resist film using a positive resist composition containing a photo acid generator for generating an acid as a result of being exposed to light on a solid phase which has a molecule immobilized thereon and having a functional group protected by an acid-decomposable protective group; (b) a step of exposing a desired position of the resist film to light; (c) a step of developing the resist film which has been subjected to development using a developing solution; and (d) a step of bringing the solid phase including the resist film which has been subjected to development into contact with a nucleotide derivative having an acid-decomposable protective group.

Also, an embodiment according to the present invention is a nucleic acid array production device which includes: a resist film formation part which is configured to form a resist film on a solid phase which has a molecule immobilized thereon and having a functional group protected by an acid-decomposable protective group; a light exposure part which is configured to expose a desired position of the resist film to light; a development part which is configured to develop the resist film which has been exposed to light; and a nucleotide derivative reaction part which is configured to bring the solid phase including the resist film which has been subjected to development into contact with a nucleotide derivative having an acid-decomposable protective group.

### BRIEF DESCRIPTION OF THE DRAWINGS

FIG. 1 is a schematic diagram of a method for producing a nucleic acid array according to an embodiment of the present invention.

FIG. 2 is a schematic diagram of a method for producing a nucleic acid array according to an embodiment of the present invention.

FIG. 3 shows an example of a device for producing a nucleic acid array according to an embodiment of the present invention.

FIG. 4 shows an example of a device for producing a nucleic acid array according to an embodiment of the present invention.

FIG. 5 shows a substrate obtained by repeatedly performing patterning light exposure and development four times.

FIG. 6 shows the results of mass distribution mapping evaluation for an organic chemical structure of a surface of a substrate which has been subjected to patterning using a time-of-flight secondary ion mass spectrometer (ToF-SIMS) and shows an MS spectrum of a deprotected portion using an acid.

FIG. 7 shows the results of mass distribution mapping evaluation for an organic chemical structure of a surface of a substrate which has been subjected to patterning using a ToF-SIMS and shows an MS spectrum of a deprotected portion using an acid.

FIG. 8 shows the results of mapping evaluation with mass derived from a fragment ion m/z 59 and m/z 303 derived from a protective group in a substrate which has been subjected to patterning.

FIG. 9 is a schematic view showing hydroxyl group formation in a portion exposed through patterning.

FIG. 10 shows a substrate obtained by performing patterning through a method according to an embodiment of the present invention.

### DESCRIPTION OF EMBODIMENTS

### <<Method for Producing Nucleic Acid Array>>

In an embodiment, the present invention provides a method for producing a nucleic acid array. A method for producing a nucleic acid array according to an embodiment includes: (a) a step of forming a resist film using a positive resist composition containing a photo acid generator for generating an acid as a result of being exposed to light on a solid phase which has molecules immobilized therein and having functional groups protected by acid-decomposable protective groups; (b) a step of exposing a desired position of the resist film to light; (c) a step of developing the resist film which has been subjected to development using a developing solution; and (d) a step of bringing the solid phase including the resist film which has been subjected to development into contact with a nucleotide derivative having acid-decomposable protective groups.

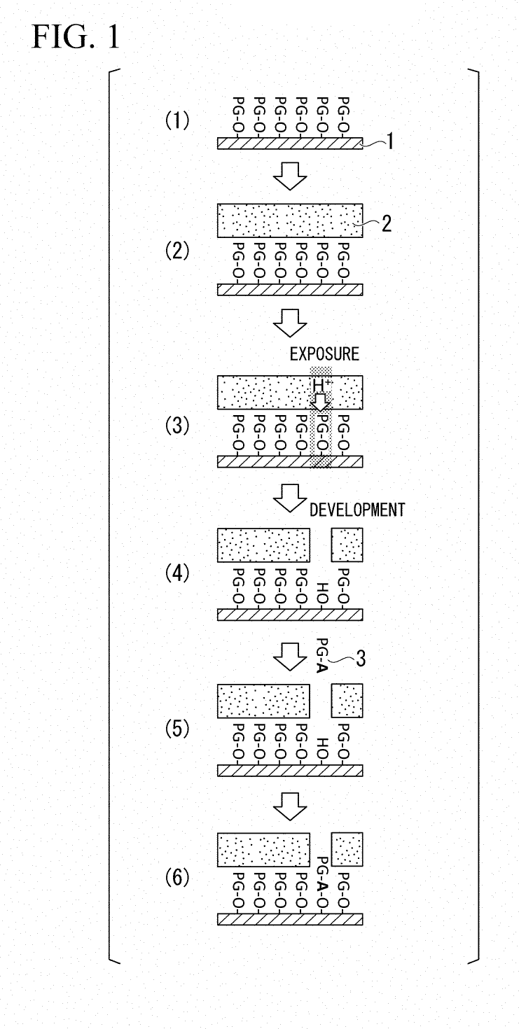

The production method of the embodiment will be described in brief with reference to FIG. 1.

First, as shown in (1) of FIG. 1, a solid phase 1 such as a substrate which has molecules immobilized therein and having functional groups protected by acid-decomposable protective groups is prepared. In the example of (1) of FIG. 1, the functional groups protected by the acid-decomposable protective groups are a hydroxyl groups. Furthermore, in the drawing, “PG” is an acid-decomposable protective group. Subsequently, as shown in (2) of FIG. 1, a resist film 2 is formed using a positive resist composition containing a photo acid generator (PAG). After that, as shown in (3) of FIG. 1, the resist film is subjected to pattern light exposure. Thus, a PAG in the resist film of the light-exposed portion generates an acid, the acid-decomposable protective groups of the underlayer of the resist film is deprotected. Through development after the light-exposure, as shown in (4) of FIG. 1, the resist film on the light-exposed portion is removed. In this state, as shown in (5) of FIG. 1, a nucleotide derivative having the acid-decomposable protective groups is caused to act. It should be noted that, in the example of (5) of FIG. 1, the nucleotide derivative is an adenine nucleotide derivative. The nucleotide derivative reacts with the deprotected functional groups, and as shown in (6) of FIG. 1, is held on the solid phase via the functional group.

The steps will be described in detail below.

### [Resist Film Formation Step]

The step (a) is a step of forming the resist film using the positive resist composition containing the photo acid generator for generating the acid as a result of being exposed to light on the solid phase which has the molecules immobilized therein and having the functional groups protected by the acid-decomposable protective groups.

In the step (a), first, as shown in (1) of FIG. 1, the solid phase which has the molecules immobilized therein and having the functional groups protected by the acid-decomposable protective groups is prepared. As the solid phase, for example, a substrate, beads, and the like can be used. When a substrate is used, examples of a material of the substrate include silicon, glass, quartz, soda lime glass, a polyamide resin, a plastic film, and the like, but the present invention is not limited thereto.

Acid-decomposable protective groups are groups that are deprotected due to the action of an acid. In the embodiment, the acid-decomposable protective groups are not particularly limited and can be used with no particular limitation as long as the acid-decomposable protective groups are deprotected due to the action of an acid. Examples of the acid-decomposable protective groups include acetyl groups (Ac); benzoyl groups (Hz); ether-based protective groups such as trityl groups (Tr), monomethoxytrityl groups (MMT), dimethoxytrityl groups (DMT), and trimethoxytrityl groups (TMT); acetal-based protective groups such as β-methoxyethoxymethylether (MEM), methoxy methyl ether groups (MOM), and tetrahydropyranyl groups (THP); silyl ether groups such as t-butyldimethylsilyl groups (TIS), and the like, but the present invention is not limited thereto. These acid-decomposable protective groups are used when the functional groups to be protected are hydroxyl groups. Even when the functional groups to be protected are amino groups or the like, suitable acid-decomposable protective groups can be appropriately selected and used. Examples of the acid-decomposable protective groups include a dimethoxytrityl (DMT) group.

In the embodiment, the functional groups of the molecules immobilized on the solid phase are protected by the acid-decomposable protective groups. The functional groups are not particularly limited as long as the functional groups can bind to the nucleotide derivative which will be described later. Examples of the functional groups include a hydroxyl group.

The method for preparing the solid phase which has the molecules immobilized therein and having the functional groups protected by the acid-decomposable protective groups is not particularly limited. For example, the method can be performed by fixing an organosilane compound molecule to a surface of the solid phase and causing the molecules having the acid-decomposable protective groups to bind to the organosilane compound molecule.

As a method for immobilizing an organosilane compound on a surface of a solid phase, for example, the surface of the solid phase is subjected to plasma treatment using oxygen gas or the like and then is caused to react to the organosilane compound in water or ethanol. Examples of the organosilane compound used in the method include hydroxyalkylsilanes, hydroxyalkyl amidosilanes, hydroxy glycol silane, and the like. For example, N-(3-triethoxysilylpropyl)-4-hydroxybutylamide) and the like can be used.

For example, the solid phase is subjected to the plasma treatment, is then immersed in an organosilane compound solution and heated at about 70 to 120° C. for about 5 to 40 minutes, and then is immersed and cleaned in an organic solvent such as isopropanol. It should be noted that, at the time of cleaning, ultrasonic treatment may be performed. After the cleaning, the solid phase is dried and heated at about 100 to 140° C. for about 1 to 10 minutes and thus the organosilane compound molecule can be fixed to the solid phase.

Subsequently, the molecules having the acid-decomposable protective groups are caused to react to the organosilane compound molecule immobilized in the solid phase. Examples of the molecules having the acid-decomposable protective groups include nucleic acid monomers and the like applicable to a phosphoroamidite method and a phosphate ester method known as nucleic acid artificial synthesis methods such as phosphoroamidite nucleotides having acid-decomposable protective groups and nucleotides whose 5′ or 3′ hydroxyl group is protected with acid-decomposable protective groups. Examples of such molecules include DMT-phosphoroamidite nucleotides. For example, molecules having acid-decomposable protective groups can be immobilized on a surface of a solid phase having an organosilane compound immobilized therein by immersing the solid phase in a phosphoroamidite nucleotide solution having acid-decomposable protective groups and shaking the mixture for about 1 to 15 minutes. This reaction may be performed under water-free conditions. After the reaction, the mixture may be appropriately cleaned with an organic solvent such as acetonitrile.

It should be noted that, although the molecules having the acid-decomposable protective groups are caused to hind to the organosilane compound molecule in the above example, the organosilane compound molecule may be protected directly with acid-decomposable protective groups.

As shown in (2) of FIG. 1, the resist film is formed on the solid phase prepared as described above using the positive resist composition containing the photo acid generator which generates an acid through light exposure.

The photo acid generator is molecules for generating an acid as a result of being exposed to light. In the production method of the embodiment, the photo acid generator is not particularly limited and can be one generally used for a resist composition and the like. Examples of the photo acid generator include onium salts such as sulfonium salts and iodonium salts, diazomethanes, sulfonic acid esters, and the like. An ionic type such as an onium salt can produce an acid stronger than that of a nonionic type such as a diazomethane or a sulfonic acid ester.

For example, the photo acid generator is an onium salt. Examples of onium salts include sulfonium salts such as triphenylsulfonium trifluoromethanesulfonate, iodonium salts such as diphenyliodonium perfluoropropanesulfonate, and the like. Examples of the acid generated from such onium salts include fluoroantimonate (HsbF₆), fluoroalkyl phosphates (FAPs), trifluoromethanesulfonic acid (CF₃SO₃H: TfOH), perfluoropropanesulfonic acid, and the like. The acid generated by the photo acid generator used in the production method of the embodiment has, for example, an acid dissociation constant (pKa) of about −30 to 5. Furthermore, for example, pKa is −25 to 0. In addition, although the photo acid generator having the solubility with respect to a solvent of about 1% by mass or more can be used, a photo acid generator having a higher solubility may be used. As the photo acid generator, for example, a photo acid generator having a solubility of 30% by mass or more, 40% by mass or more, or 50% by mass or more with respect to propylene glycol monomethyl ether acetate (PGMFA) may be used. A photo acid generator that is commercially available for a resist composition or the like can also be used as the photo acid generator. For example, a photo acid generator of the CPI (registered trademark) series manufactured by San-Apro Ltd. can be used. As the PAG of the CPI (registered trademark) series, CPI-210S is an exemplary example.

The positive resist composition is a resist composition in which the solubility with respect to a developing solution increases due to light exposure. In the production method in the embodiment, a generally used positive resist composition can be used without particular limitation. The positive resist composition may be for ultraviolet light such as g rays, h rays, and i rays; for an excimer laser such as an ArF excimer laser and a KrF excimer laser; for extreme ultraviolet (EUV), for vacuum ultraviolet (VUV), for an electron beam (EB), for X rays, and the like. As an example, a positive resist composition can be used exclusively for i rays. Furthermore, as the positive resist composition, for example, a positive resist composition containing a novolac resin (a novolac-based resist) may be used. A commercially available product may be used as the positive resist composition. In addition, examples of the positive resist composition include Sumiresist (registered trademark) (manufactured by Sumitomo Chemical Co., Ltd.), PFR series (manufactured by JSR Corporation), and OFPR series (manufactured by Tokyo Ohka Co., Ltd.).

The amount of the photo acid generator with respect to the positive resist composition is not particularly limited and can be, for example, 0.005 to 10% by mass, 0.5 to 5% by mass, 1.0 to 3% by mass, and the like.

Also, when a commercially available positive resist composition is used, a photo acid generator may already be added in some cases. In this case, the photo acid generator may or may not be added additionally.

It should be noted that, when a commercially available positive resist composition is used, in a case in which a photo acid generator is not added to the commercially available positive resist composition, an appropriate photo acid generator is added. For example, since a photo acid generator is not added to Sumiresist (registered trademark) manufactured by Sumitomo Chemical Co., Ltd., an appropriate photo acid generator (for example, CPI series manufactured by San-Apro and the like) is added and used.

A resist film using a positive resist composition may be formed using a method generally used for forming a resist film. For example, a spin coating method, a dip coating method, a slit die coating method, a spray coating method, or the like can be used. A thickness of the resist film formed on the solid phase is not particularly limited, and can be, for example, about 50 nm to 30 μm, about 80 nm to 25 μm, and about 100 nm to 20 μm.

It should be noted that the step (a) may include an operation of performing hydrophobization treatment on a solid phase which has molecules immobilized therein and having functional groups protected by acid-decomposable protective groups, before an operation of forming a resist film. A method for performing hydrophobization treatment is not particularly limited and it is possible to use a hydrophobization treatment method generally performed on a solid phase at the time of forming a resist film. Examples of the method for performing hydrophobization treatment include treatment with hexamethylene disilazane (HMDS). For example, it is possible to perform hydrophobization treatment by applying HMDS to a solid phase immobilized therein and having functional groups protected by acid-decomposable protective groups using a spin coating method or the like and heating the solid phase having HMDS applied thereto at about 70 to 130° C. for about 20 seconds to 5 minutes. By performing hydrophobization treatment, it is possible to enhance the adhesion of the resist film to the solid phase. Thus, even if light exposure and development are repeatedly performed a plurality of times on the same resist film, the resolution of patterning can be easily maintained.

### [Light Exposure Step]

The step (b) is a step of exposing a desired position of the resist film formed in the above step (a) to light.

As shown in (3) of FIG. 1, when the resist film 2 is subjected to pattern light exposure, an acid is generated by the photo acid generator contained in the resist film 2 in the light-exposed portion. The acid-decomposable protective groups (PG) present in the underlayer of the light-exposed portion of the resist film 2 are deprotected and the functional groups protected by the acid-decomposable protective groups are exposed.

Light exposure in the step (b) can be performed using an appropriate light source configured to radiate g rays, h rays, i rays, an ArF excimer laser, a KrF excimer laser, an EUV, a VUV, an EB, X rays, or the like in accordance with types of the photo acid generator and the resist composition. For example, when a photo acid generator for ArF or a positive resist composition for ArF is used, it is possible to perform light exposure using an ArF excimer laser. Furthermore, when an acid generator for i rays or a positive resist composition for i rays is used, it is possible to perform light exposure using i rays.

In the light exposure in the step (b), an amount of light exposure is not particularly limited, but can be, for example, 10 to 600 mJ/cm² or 50 to 200 mJ/cm². In a method for producing an Affymetrix type DNA micro-array, several J or more are necessary for deprotection of photosensitive bases, and in the production method of the embodiment, a nucleic acid array can be produced with a smaller amount of light exposure as compared to the Affymetrix type method.

The light exposure is performed only on the resist film at a desired position at which the nucleotide derivative is caused to bind in a step of bringing the resist film into contact with the nucleotide derivative having the acid-decomposable protective groups which will be described later. By performing such pattern light exposure, only the acid-decomposable protective groups present on the underlayer of a portion of the resist film which has been exposed to light are deprotected and acid-decomposable protective groups of a non-light-exposed portion remain without being deprotected. In the case of such pattern light exposure, for example, contact light exposure and proximity light exposure as a method for performing pattern light exposure using a photomask or the like, projection light exposure using an optical system such as a lens and a mirror, and the like can be used. A metal mask or a film mask may be used instead of a photomask and a means such as a spatial light modulation element or maskless light exposure using a laser beam may be used.

It should be noted that a post exposure hake (PEB) may or may not be performed. For example, in the production method in the embodiment, the PHB is not performed. By not performing the PEB, it is possible to reduce a temperature of a series of steps and minimize a thermal cross-linking reaction in the resist film. Thus, even if light exposure and development are repeatedly performed a plurality of times on the same resist film, the resolution of patterning can be easily maintained.

[Development Step]

The step (c) is a step of developing the resist film which has been subjected to light exposure in the step (b) described above using a developing solution.

As shown in (4) of FIG. 1, using the development, a portion of the resist film 2 which has been subjected to light exposure in the step (b) is removed and the functional groups in the underlayer of the resist film 2 are exposed.

The development can be performed using the developing solution generally used for positive development of a positive resist film. For example, as the developing solution, an aqueous solution of about 0.1 to 10% by mass of tetramethylammonium hydroxide (TMAH) can be used. The developing solution is not limited to TMAH and examples of the developing solution can also include aqueous solutions of organic bases such as triethylamine and trimethylamine; sodium hydroxide; metal salts of metal ions with carbonate ions, bicarbonate ions, silicate ions, and the like. Examples of metal salts include, but are not limited to, alkali metal salts such as sodium salts, alkaline earth metal salts such as magnesium salts, and the like.

As a development method, methods generally used for development of positive resist films such as an immersion method, a paddle method, and a spray method can be used.

Also, the step (c) may include an operation of irradiating the resist film with ultrasonic waves.

In this case, the resist film may be irradiated with ultrasonic waves while developing the resist film using a developing solution. For example, it is possible to perform irradiation of ultrasonic waves at about 15 to 40 kHz or 20 to 35 kHz while the solid phase including the resist film is immersed in the developing solution. By performing the irradiation of ultrasonic waves, a development time can be shortened. For example, when the development is performed while performing irradiation of ultrasonic waves, the development time can be about 20 seconds to 5 minutes, about 30 seconds to 3 minutes, and about 40 to 80 seconds. Particularly, when the step (b) and the step (c) are performed a plurality of times on the same resist film, the development time in the step (c) may be 80 seconds or less. By performing the irradiation of ultrasonic waves, the development can be completed in a short development time and thus it is possible to reduce an influence of the developing solution on the non-light-exposed portion. Therefore, even if exposure and development are repeatedly performed a plurality of times on the same resist film, a clean pattern can be obtained through a short development.

It should be noted that the method of the embodiment may include a step of cleaning the resist film after the resist film is developed in the step (c) and before the step (d) which will be described later. In this case, a cleaning solution may be a cleaning solution generally used for cleaning the resist film after the development and may be an aqueous solvent or an organic solvent. For example, water can be used as the aqueous solvent and toluene, acetone, or the like can be used as the organic solvent. As the cleaning solution, a cleaning solution which can remove only the contaminant components and particles without attacking the resist film can be appropriately selected and used. A mixed solvent obtained by combining a plurality types of solvents may be used as appropriate in consideration of the polarity and solubility parameters. Furthermore, a combination of the cleaning using the aqueous solvent and the cleaning using the organic solvent may be performed. Moreover, the irradiation of ultrasonic waves can also be performed during the cleaning. The irradiation of ultrasonic waves can be performed, for example, at about 15 to 40 kHz or at about 20 to 35 kHz. By performing the cleaning operation, it is possible to remove the resist residue remaining in the light-exposed portion.

[Nucleotide Derivative Reaction Step]

The step (d) is a step of bringing the solid phase including the developed resist film which has been subjected to development in the step (c) described above into contact with the nucleotide derivative having the acid-decomposable protective groups.

As shown in (5) and (6) of FIG. 1, when the nucleotide derivative 3 having the acid-decomposable protective groups is brought into contact with the solid phase 1 including the resist film 2 which has been subjected to development, the nucleotide derivative 3 is coupled with and binds to the functional groups which has been exposed through the light exposure and development. Thus, nucleic acid synthesis can be performed at a desired position on the solid phase.

In the case of the nucleotide derivative having the acid-decomposable protective groups, a nucleotide derivative used for a general nucleic acid synthesis method can be used. As the nucleic acid synthesis method, for example, a phosphoroamidite method is an exemplary example, and as the nucleotide derivative, phosphoroamidated nucleotide derivatives can be used. Furthermore, the acid-decomposable protective groups can be used with no particular limitation as long as the acid-decomposable protective groups are deprotected due to the action of an acid. As the acid-decomposable protective groups, for example, acid-decomposable protective groups described in the above-described “[Resist film formation step]” and the like is an exemplary example. For example, DMT can be used as one of the acid-decomposable protective groups. Furthermore, as the functional groups protected by the acid-decomposable protective groups, a hydroxyl group binding to a carbon atom at the 5-position of ribose or deoxyribose is an exemplary example, but the present invention is not limited thereto. Examples of the nucleotide derivative which can be used in this step include DMT-dA phosphoroamidite, DMT-dT phosphoroamidite, DMT-dG phosphoroamidite, DMT-dC phosphoroamidite, and the like, but the present invention is not limited thereto. Nucleotide derivatives commercially available for nucleic acid synthesis may be used as the nucleotide derivative. Furthermore, a nucleotide from which the nucleotide derivative is derived may be RNA and artificial nucleic acids such as bridged nucleic acids (BNA) and peptide nucleic acids (PNA).

When the phosphoroamidated nucleotide derivative is used as the nucleotide derivative, the reaction of the nucleotide derivative with the functional groups on the solid phase can be performed under the conditions used in a general phosphoroamidite method. For example, nucleic acid synthesis using the phosphoroamidite method can be performed in accordance with the following procedure.

First, the phosphoroamidated nucleotide derivative is activated with tetrazole or the like and the nucleotide derivative is coupled with the functional groups on the solid phase. Subsequently, the unreacted functional groups are capped through acetylation or the like not to participate in the subsequent cycles. After that, the binding of the functional groups on the solid phase to the nucleotide derivative is oxidized using iodine so that trivalent phosphorus is converted to pentavalent phosphate ester.

These reactions are known and can be performed under known conditions. Furthermore, commercially available reagents can be used as a reagent used for these reactions. It should be noted that the above-described method is an example of a method for binding the functional groups on the solid phase to the nucleotide derivative and the binding reaction may be performed using other methods.

Before the reaction with the nucleotide derivative is performed, the solid phase may be dried. In the case of the drying, for example, dried acetonitrile, nitrogen flow, and the like can be used. Furthermore, the binding reaction of the functional groups on the solid phase to the nucleotide derivative may be performed under water-free conditions.

### [Nucleic Acid Synthesis Through Multiple Exposure]

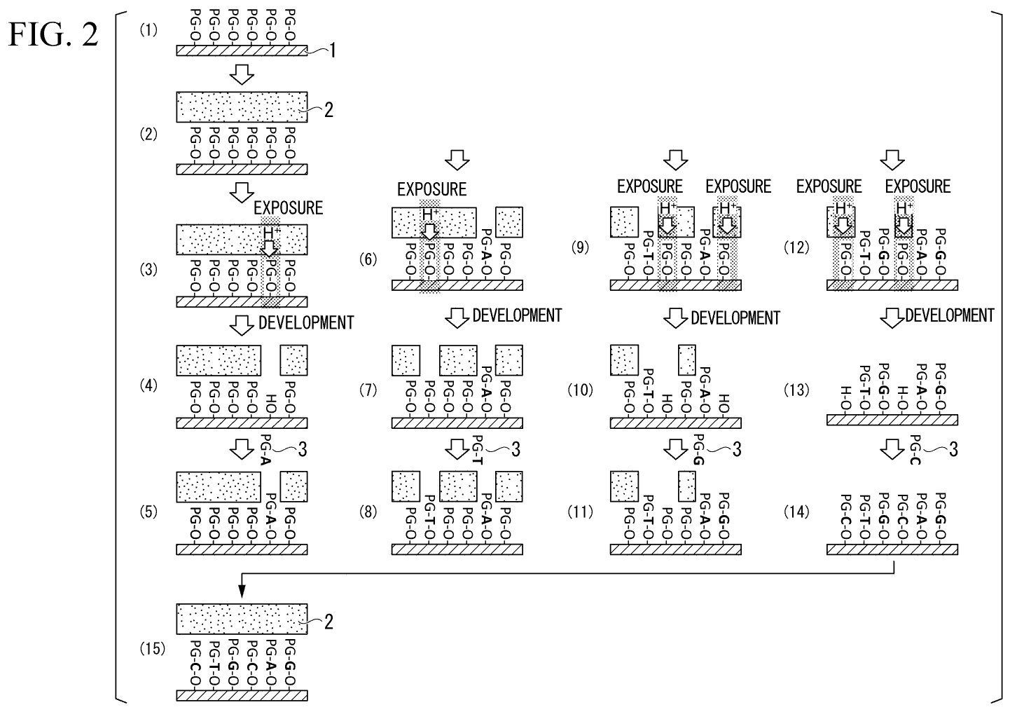

The resist film formed in the step (a) can be patterned with high resolution even if the exposure and development steps (steps (b) and (c)) are repeatedly performed a plurality of times. Thus, in the production method of the embodiment, as shown in FIG. 2, after the resist film is formed in the step (a), the steps from the exposure step in the step (b) to the nucleotide derivative reaction step in the step (d) may be repeatedly performed a plurality of times. By repeatedly performing exposure and development on the same resist film, it is possible to reduce the number of steps and cost for forming the resist film. For example, in order to use four types of nucleotide derivatives having adenine, thymine, cytosine, and guanine as bases for DNA synthesis, as shown in FIG. 2, after forming a resist film, the exposure step of the step (b) to the nucleotide derivative reaction step of the step (d) may be repeatedly performed four times.

When the steps (b) to (d) are repeatedly performed on the same resist film, in the exposure step of step (b), as shown in (3), (6), (9), and (12) of FIG. 2, different portions of the resist film are exposed to light for each exposure step. Furthermore, in the step (d), different nucleotide derivatives are used as shown in (5), (8), (11), and (14) of FIG. 2. Thus, it is possible to cause a desired nucleotide derivative to hind to a desired position on the solid phase. It should be noted that, in the example of FIG. 2, the nucleotide derivative is caused to react with adenine, thymine, guanine, and cytosine in this order, but the order of reacting the nucleotide derivative is not limited to this and the nucleotide derivative can be caused to react in any order.

When the steps (b) to (d) are completed, the process returns to the process of the step (a) to form a resist film ((15) of FIG. 2). Furthermore, by repeatedly performing the steps (h) to (d) again, a nucleic acid having a desired sequence can be synthesized at a desired position on the solid phase. In this way, a nucleic acid with 10 to 100 bases having any sequence can be synthesized on the solid phase to produce a nucleic acid array. When the nucleic acid with 10 to 100 bases is synthesized, it is possible to synthesize the nucleic acid having the above base length by repeatedly performing the step (a) and repeatedly performing the steps (b) to (d) four times by changing a type of nucleotide derivative each time 10 to 100 times. That is to say, it is possible to synthesize a nucleic acid having an arbitrary base length by repeatedly performing performance of the step (a) and repeatedly performing the steps (b) to (d) four times by changing a type of nucleotide derivative each time an arbitrary number of times.

It should be noted that, in the production method of the embodiment, the steps (b) to (d) may be performed only once or may be performed two or three times without necessarily repeatedly performing the steps (b) to (d) four times after performing the step (a). Furthermore, after the step (d), the remaining resist film may be removed and the process may return to the process of the step (a) again to form a resist film.

According to the production method in the embodiment, a nucleic acid array can be produced using a smaller amount of light exposure than that of a conventional method. Furthermore, by repeatedly performing the exposure, development, nucleotide derivative binding reaction on the same resist film, it is possible to reduce the number of steps and cost for synthesizing a nucleic acid. In addition, the fining of an array is also possible by controlling the pattern light exposure.

For this reason, according to the production method in the embodiment, it is possible to provide a method for producing a nucleic acid array which enables the fining of an array and has a high throughput.

### <<Device for Producing Nucleic Acid Array>>

In an embodiment, the present invention provides a device for producing a nucleic acid array for realizing the method for producing a nucleic acid array in the embodiment. The device for producing a nucleic acid array according to an embodiment includes a resist film formation part which is configured to form a resist film on a solid phase which has molecules immobilized therein and having functional groups protected by acid-decomposable protective groups, a light exposure part which is configured to expose a desired position of the resist film to light, a development part which is configured to develop the resist film which has been exposed to light, and a nucleotide derivative reaction part which is configured to bring the solid phase including the resist film which has been subjected to development into contact with a nucleotide derivative having acid-decomposable protective groups.

An example of a constitution of the device for producing a nucleic acid array in the embodiment will be described below.

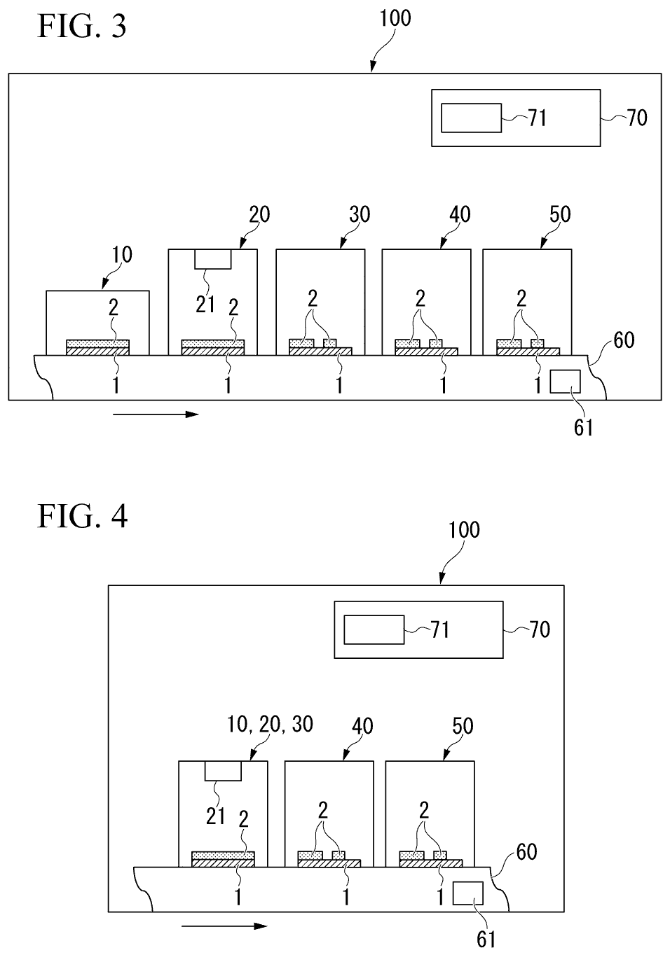

FIG. 3 shows an example of a constitution of the device for producing a nucleic acid array in the embodiment. In the example of the device shown in FIG. 3, a nucleic acid array production device 100 includes a resist film formation part 10, a light exposure part 20, a development part 30, and a nucleotide derivative reaction part 40.

The resist film formation part 10 has a mechanism for forming a resist film 2 on a solid phase 1 which has molecules immobilized therein and having functional groups protected by acid-decomposable protective groups. The resist film formation part 10 can include, for example, a solid phase holding part which holds a solid phase such as a substrate, a resist composition application part which applies a positive resist composition containing a photo acid generator on the solid phase, and a spin coat part which spin-coats the resist composition on the solid phase. A film made of the resist composition may be formed on the solid phase through a dip coater, a slit die coater, a spray coater, or the like as well as a spin coater. In this case, the resist film formation part includes a dip coating part, a slit die coating part, or a spray coating part instead of the spin coat part. Furthermore, the resist film formation part 10 may optionally include a plasma treatment part which performs plasma treatment on the solid phase, a silanization part which causes an organosilane compound to bind to (perform silanization on) a surface of the solid phase, a hydrophobization treatment part which performs hydrophobization treatment on a surface of the solid phase, and the like. Furthermore, the resist film formation pan 10 can also include a drying part or the like configured to dry the solid phase which has been subjected to the hydrophobization treatment.

The light exposure part 20 includes a mechanism for exposing a desired position of the resist film 2 to light. The light exposure part 20 can include a light source 21 for light exposure. Furthermore, a photomask through which a desired position of the resist film 2 is exposed to light, a light exposure pattern storage part for storing a light exposure pattern, and the like may be provided. In addition, means for projection light exposure using an optical system such as a lens and a mirror, maskless light exposure using a spatial light modulation element and a laser beam, and the like may be provided instead of the photomask.

The development part 30 has a mechanism for developing a resist film which has been exposed to light. The development part 30 can include an immersion part in which the solid phase 1 is immersed in a developing solution, a developing solution injection part which injects a developing solution into the immersion part, and the like. Furthermore, optionally, an ultrasonic wave irradiation part which irradiates a resist film being developed with ultrasonic waves may be provided. It should be noted that, since the development proceeds at a solid/liquid interface, development may be adopted as long as a required amount of developing solution is in contact with the solid phase 1 and it is not necessary to necessarily perform development through immersion. For this reason, instead of the immersion part, for example, a constitution in which a required amount of developing solution is applied to a resist film using a slit die coater, a spray coater, or the like may be provided and a constitution in which a predetermined time is held after a small amount of developing solution is applied to the entire resist film on a solid phase using a spin coater may be provided. With such a constitution, the cost of the developing solution can be significantly reduced as compared to when an immersion method is performed.

Also, the development part 30 can also include a cleaning part which washes the solid phase 1 which has been subjected to development, a drying part which dries the solid phase 1 which has been subjected to cleaning.

The nucleotide derivative reaction part 40 has a mechanism for bringing the solid phase 1 including the resist film which has been subjected to development into contact with a nucleotide derivative having acid-decomposable protective groups. The nucleotide derivative reaction part 40 can include a reaction tank configured to react a nucleotide derivative, a nucleotide derivative addition part configured to add the nucleotide derivative to the reaction tank, and the like. Furthermore, the nucleotide derivative reaction part 40 may include an atmosphere controller which controls an atmosphere such as a dry atmosphere and an inert atmosphere. After the nucleotide derivative is introduced into the solid phase 1, a reaction tank in which an oxidation reaction/capping reaction performed using a general artificial nucleic acid synthesis method is possible, a chemical solution addition part configured to add a chemical solution necessary for these reactions, and the like can also be provided. Furthermore, when nucleic acid synthesis is performed using the phosphoroamidite method, an operation part configured to perform various operations of the phosphoroamidite method and the like may be provided.

The nucleic acid array production device 100 may optionally include a cleaning part 50 configured to clean the solid phase 1 into which the nucleotide derivative has been introduced. When the cleaning is performed through dissolution using a solvent, the cleaning part 50 can also include an immersion cleaning tank in which nucleotide introduction reagents and reagents used in an oxidation reaction/capping reaction are removed. A steam cleaning tank may be provided as a cleaning tank. A constitution in which liquid cleaning in the immersion tank or steam cleaning in the steam cleaning tank is performed independently and a constitution in which cleaning using the steam cleaning tank is performed after cleaning in the immersion tank may be provided.

Also, the nucleic acid array production device 100 may include a solid phase moving part 60 which moves the solid phase 1 to the resist film formation part 10, the light exposure part 20, or the development part 30 and a solid phase moving controller 61 which controls the movement of the solid phase moving part 60. Thus, it is possible to efficiently produce a nucleic acid array by automatically moving the solid phase 1 to the resist film formation part 10, the light exposure part 20, or the development part 30. The solid phase moving part 60 may also be configured to move the solid phase 1 to the nucleotide derivative reaction pan 40 (for example, FIG. 3). Furthermore, when a constitution in which the same resist film is subjected to exposure/development a plurality of times is provided, the solid phase moving pan 60 can also be configured to circulate the solid phase 1 a predetermined number of times (for example, four times) between the light exposure part 20, the development part 30, and the nucleotide derivative reaction part 40. Moreover, a constitution in which, after completion of the predetermined number of circulations, the solid phase 1 may be returned to the resist film formation part 10 may be provided. It should be noted that, although the solid phase moving part 60 has a belt-like constitution in which the parts are connected in the example of FIG. 3, the constitution of the solid phase moving part 60 is not limited thereto, and for example, the solid phase 1 may be configured to move by an arm or the like.

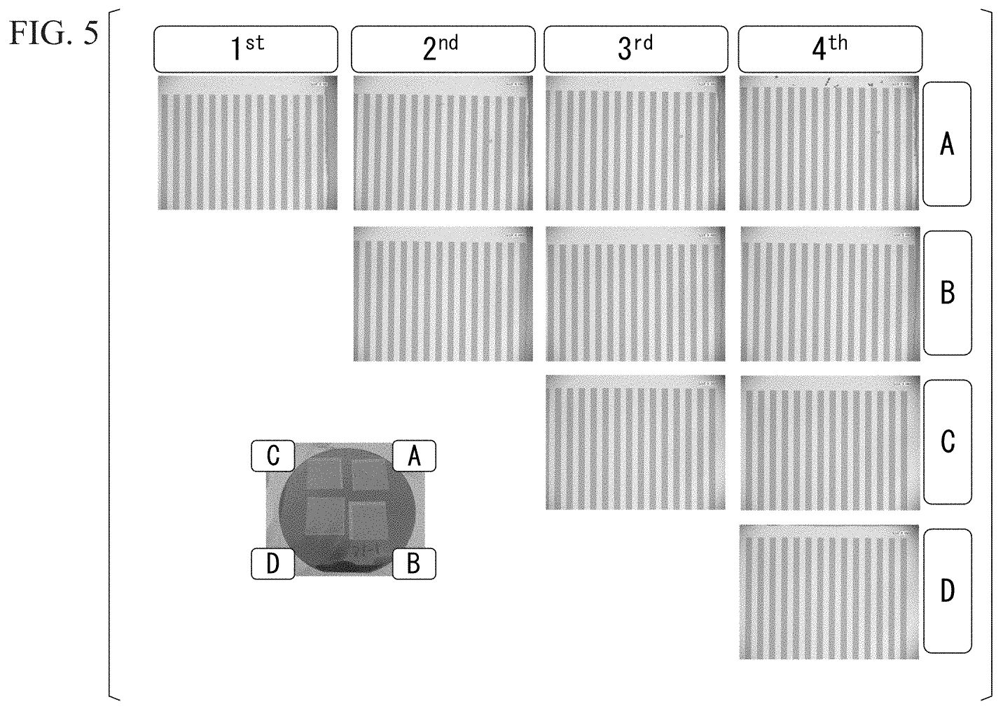

Furthermore, in the nucleic acid array production device 100, the light source 21 of the light exposure part 20 may be disposed above the resist film formation part 10 (for example, FIG. 4). For example, when a resist film is formed using spin coating, a light source of a light exposure part may be disposed directly above a rotation table of a spin coater. With such a constitution, it is possible to continuously perform the resist film formation step and the light exposure step without moving the solid phase. In this case, all or a part of the resist film formation part 10 is configured to be used as the light exposure part 20 as well.

In addition, in the nucleic acid array production device 100, all or a part of the resist film formation part 10 may also be used as the development part 30 (for example, FIG. 4). As described above, the development in the device for producing a nucleic acid array need not to necessarily include the immersion of the solid phase into the developing solution and it is also possible to perform the development by applying a small amount of developing solution. For this reason, for example, a spin coater, a slit die coater, a spray coater, or the like disposed in the resist film formation part 10 may be used for applying a solvent to the resist film. With such a constitution, the resist film formation step, the light exposure step, and the development step can be continuously performed without moving the solid phase.

The nucleic acid array production device 100 can include a controller 70 which controls an operation of each of the above-mentioned parts, an array arrangement storage part 71 which stores the sequence of each probe in a nucleic acid array, and the like as arbitrary constituent elements in addition to the above-mentioned parts.

An example of an operation of the nucleic acid array production device 100 including the above-described constituent elements will be described.

First, in the resist film formation part 10, the resist film 2 is formed on the solid phase 1. Furthermore, if necessary, before formation of the resist film 2, the surface of the solid phase 1 is subjected to plasma treatment and silanization using the plasma treatment part and the silanization part. For example, after silanization, a solid phase 1 which has molecules having functional groups protected by acid-decomposable protective groups is immobilized therein using a method for causing molecules having acid-decomposable protective groups to bind to an organosilane compound on the solid phase, and if necessary, the surface of the solid phase 1 is subjected to hydrophobization in the hydrophobization part and the solid phase 1 which has been subjected to hydrophobization is dried in the drying part. The resist composition is applied on the dried solid phase 1 using the resist composition application part and the resist film 2 is formed using the spin coat part or the like. After the resist film 2 is formed in the resist film formation part 10, the solid phase 1 is transported to the light exposure part 20 using the solid phase moving part 60.

In the light exposure part 20, pattern light exposure is performed on the resist film 2. In the light exposure part 20, for example, a predetermined position of the resist film 2 is exposed to light on the basis of information of the light exposure pattern storage part or the like. An amount of light exposure at the light exposure part 20 is controlled to be, for example, 10 to 600 ml/cm². At the light-exposed position of the resist film 2, the photo acid generator generates an acid and the acid-decomposable protective groups located at the underlayer of the light-exposed portion in the resist film 2 are deprotected. After the resist film 2 is exposed to light in the light exposure part 20, the solid phase 1 is transported to the development part 30 using the solid phase moving part 60.

In the development part 30, the resist film 2 which has been subjected to development is developed. In the development part 30, for example, development is performed by immersing the solid phase in a developing solution in the immersion part. In the development part 30, irradiation of ultrasonic waves is performed on the resist film 2 using an ultrasonic wave irradiation part as necessary. A portion of the resist film at a position which has been subjected to light exposure in the light exposure part 20 through the development is removed and the functional groups included in the molecules binding to the solid phase 1 are exposed. The solid phase 1 which has been subjected to development is optionally cleaned and dried in the cleaning part and the drying part. After the resist film 2 is developed in the development part 30, the solid phase 1 is transported to the nucleotide derivative reaction part 40 using the solid phase moving part 60.

In the nucleotide derivative reaction part 40, the solid phase 1 including the resist film 2 which has been subjected to development is brought into contact with a nucleotide derivative having acid-decomposable protective groups. Thus, the nucleotide derivative binds to the functional groups on the solid phase 1. In the nucleotide derivative reaction part 40, for example, the solid phase 1 is brought into contact with the nucleotide derivative in the reaction tank and is subjected to various operations of the phosphoroamidite method.

The solid phase 1 after the reaction in the nucleotide derivative reaction part 40 may be subjected to exposure, development, and a nucleotide derivative reaction again in the light exposure part 20, the development part 30, and the nucleotide derivative reaction part 40 without passing through the resist film formation part 10. Alternatively, the solid phase 1 after the reaction in the nucleotide derivative reaction part 40 may be returned to the resist film formation part 10 to form a resist film 2. It should be noted that, when the exposure in the light exposure part 20, the development in the development part 30, and the nucleotide derivative reaction in the nucleotide derivative reaction part are repeatedly performed after the resist film 2 is formed, the number of repetitions is controlled to be up to four times. After the completion of the predetermined number of repetitions, the solid phase 1 is returned to the resist film formation part 10 and a resist film 2 is formed.

As described above, it is possible to produce a nucleic acid array having a desired sequence by repeatedly performing resist film formation, exposure, development, and a nucleotide derivative reaction any number of times.

It should be noted that, although the solid phase 1 is transported to each of the parts using the solid phase moving part 60 in the above-mentioned example, for example, the solid phase 1 may be held in one place, each of the parts of the nucleic acid array production device 100 may be moved to the fixed position of the solid phase 1 to be subjected to each of the steps.

Although the embodiment of the present invention has been described in detail below with reference to the drawings, the specific constitution thereof is not limited to this embodiment and includes any design and the like without departing the gist of the present invention.

### EXAMPLES

Although the present invention will be described below by way of examples, the present invention is not limited to the following examples.

### Example 1

### [Formation of Linker Layer on Substrate and Introduction of Acid-Decomposable Protective Group]

150 mg of a silane coupling agent (N-(3-triethoxysilylpropyl)-4-hydroxybutylamide manufactured by GELEST, INC.) was weighed in a beaker and 150 ml, of ion exchange water heated to 90° C. was added into the beaker. After performing stirring at 90° C. or 5 minutes, 1.5 mL of acetic acid was added and the mixture was additionally heated and stirred for 30 minutes to form a silane solution.

Subsequently, a 3-inch silicon wafer with a 150 nm thermal oxide film serving as a substrate was treated and activated at 400 W×3 times using an atmospheric pressure oxygen plasma device (YAP510: manufactured by Yamato Scientific Co., Ltd.) and then was put into a reaction container and was heated with the silane solution at a set temperature of 90° C. for 20 minutes.

After the heating, the substrate was taken outside of the container, was immersed in isopropanol (IPA), and was subjected to 28 kHz ultrasonic cleaning for 5 minutes, and then was dried using a nitrogen flow. After that, the silane was fixed to the substrate by performing heating at 120° C. for 3 minutes to form a linker layer.

It should be noted that, if necessary, the linker layer was formed only on one side of the substrate by attaching a masking tape (N380 manufactured by Nitto Denko Corporation) to the one side thereof before the plasma treatment and peeling the masking tape before the IPA cleaning.

Subsequently, the following work was performed in a glove box controlled to a nitrogen atmosphere of an oxygen concentration of 0. 0% and a humidity of 3.3% or less.

20 mL of an acetonitrile solution of tetrazole (450 mM manufactured by Sigma-Aldrich) and 10 ml, of dried acetonitrile (manufactured by Sigma-Aldrich) were added to 1 g of dimethoxytrityl (DMT)-dT phosphoroamidite (manufactured by Sigma-Aldrich). Thus, 30 mL of a 45 mM solution of DMT-dT was prepared.

As described above, the substrate having the linker layer formed thereon was immersed in the dried acetonitrile and was dried using a nitrogen flow. After the drying, the substrate was put into a reaction container and shaken with the DMT-dT solution for 2 minutes. The substrate was taken outside of the container and the dried acetonitrile was put into another container for transportation with the substrate and taken outside of the glove box.

The substrate was immersed in a container for cleaning containing 100 ml, of acetonitrile and subjected to 28 kHz ultrasonic cleaning for 5 minutes. 100 mL of acetonitrile was prepared in another container and the same cleaning was performed twice or more, i.e., a total of 3 times. After the drying using a nitrogen flow, the substrate was stored in a glove box.

### [Preparation of Resist Composition]

A photo acid generator (CPI-210S manufactured by San-Apro Co., Ltd.) was added to Sumiresist (PHR-34A6 manufactured by Sumitomo Chemical Co., Ltd.) to obtain 1. 2% by mass. The mixture was stirred using a rotary kneader and further irradiated with 28 kH ultrasonic waves for 5 minutes to completely dissolve the PAG.

### [Formation of Resist Film]

A layer of hexamethylene disilazane (HMDS) was spin-formed (1000 rpm and 30 seconds) on the substrate prepared as described above and the above-mentioned resist composition was heated and dried at 110° C. for 1 minute using a hot plate. Furthermore, a film of the above-mentioned resist solution was spin-formed (1000 rpm and 30 seconds).

### [Patterning Through Multiple Exposure]

Pattern exposure was performed on a portion A shown in the lower left side of FIG. 5 with UV light of 365 nm. After the exposure, each substrate included in A to D was immersed in an aqueous solution of tetramethylammonium hydride (TMAH) and developed at 22° C. for 1 minute while radiating 28 kHz ultrasonic waves, thereby forming stripped opening portions (A of FIG. 5/1st).

Subsequently, pattern exposure was performed on a portion B with UV light of 365 nm and development was similarly performed to form a new opening portion (B of FIG. 5/2nd). Although the resist film was the resist film which had been subjected to the developing step once, it was confirmed that the clear patterning was performed. Furthermore, it was confirmed that the portion A was not damaged even if the development step was performed twice (A of FIG. 5/2nd).

Similarly, pattern exposure was performed on portions C and D and patterning was performed four times by repeatedly performing the developing operation. In any of the first to fourth pattern exposures, resists could be drawn with the same resolution (A of FIG. 5/1st, B of FIG. 5/2nd, C of FIG. 5/3rd, and D of FIG. 5/4th). Furthermore, no damage was observed in the formed patterns even after a plurality of exposure and development steps (A to C of FIG. 5/4th).

### [Evaluation of Patterning]

Mapping evaluation using mass distribution was performed by analyzing and interpreting the mass of the organic chemical structure on the substrate using a time-of-flight secondary ion mass spectrometer (ToF-SIMS). At the time of analysis, the substrate was immersed and cleaned in acetone to peel the resist.

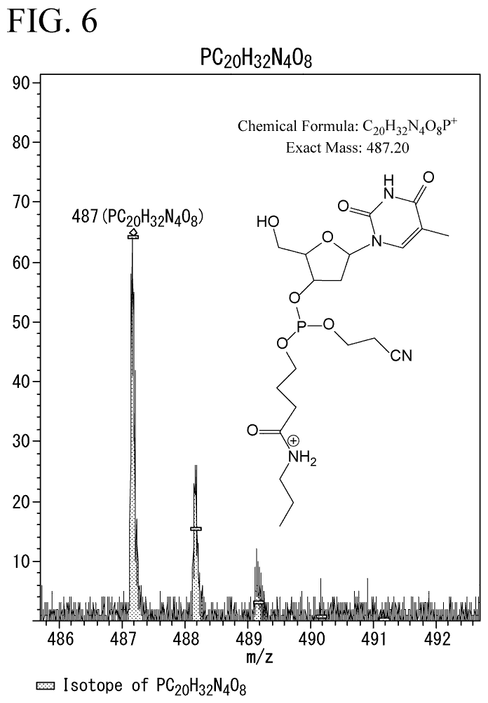

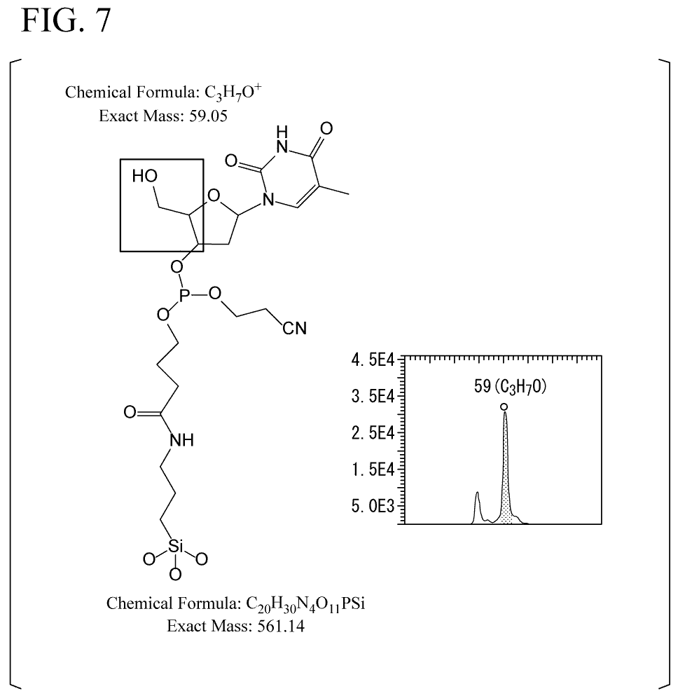

FIGS. 6 and 7 show MS spectra of a portion deprotected using an acid. m/z 59 (FIG. 7) corresponding to fragment ion peaks and m/n=487 (FIG. 6) corresponding to molecule ion peaks were detected and it was possible to assign the deprotected structure.

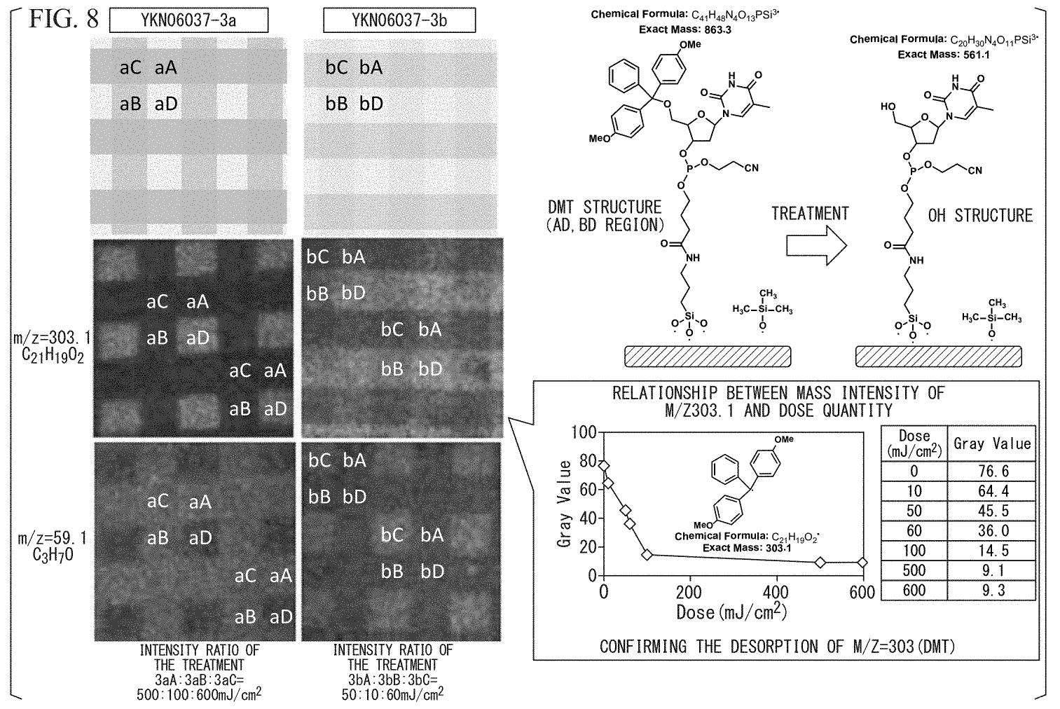

FIG. 8 shows the results of the mapping evaluation with mass derived from a fragment ion m/z 59 and m/z 303 derived from the protective group in the substrate patterned through the method associated with the present invention. It was seen that the protective group decreased and the number of deprotected structures increased in accordance with an amount of light exposure and that regioselective deprotection occurred.

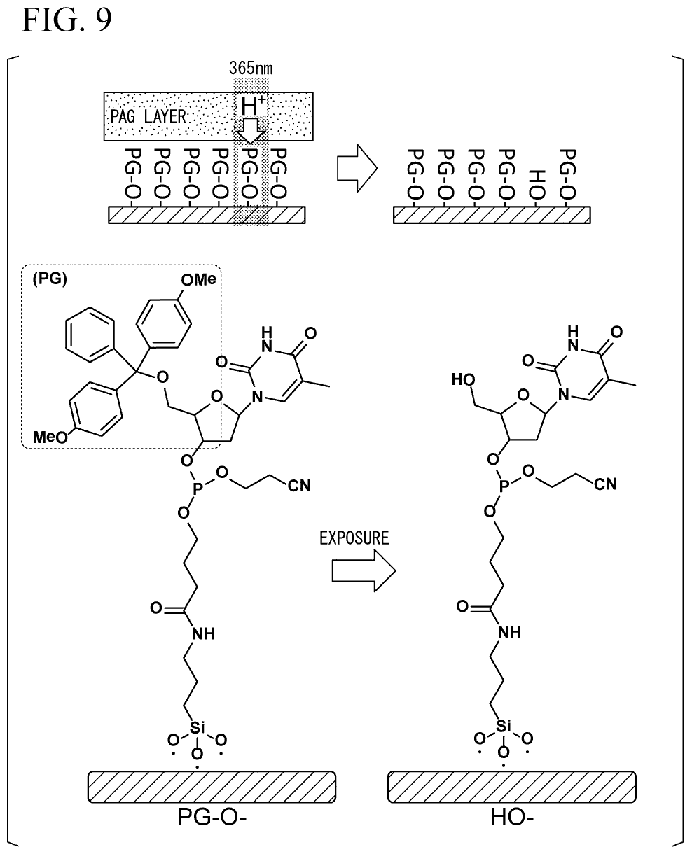

As shown in FIG. 9, since a hydroxyl group was able to be generated only in the light-exposed portion, it can be said that the present technology makes it possible to produce a DNA chip using light processing using an artificial DNA synthesis method such as a phosphoroamidite method.

### Example 2

After a film of HMDS was spin-formed (1000 rpm and 30 seconds), a resist film was formed in the same manner as in Example 1 except that a heating temperature using a hot plate was set to 90° C. After that, as in Example 1, pattern exposure was performed and developed.

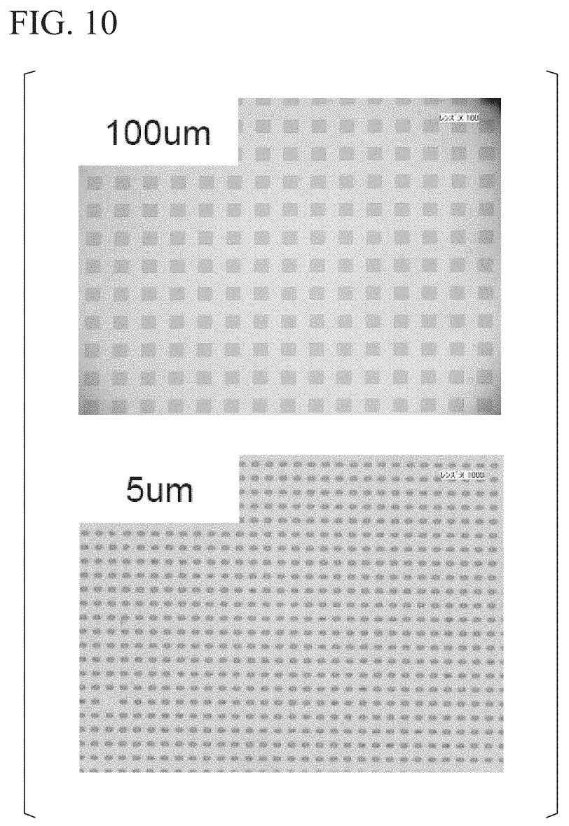

FIG. 10 shows the substrate that was subjected to patterning. Pattern formation could be performed not only at intervals of 100 μm but also at intervals of 5 μm.

What is claimed is:

1. A method for producing a nucleic acid array, comprising:
(a) a step of forming a resist film using a positive resist composition containing a photo acid generator for generating an acid as a result of being exposed to light on a solid phase which has a molecule immobilized thereon and having a functional group protected by an acid-decomposable protective group;
(b) a step of exposing a desired position of the resist film to light;
(c) a step of developing the resist film which has been exposed to light using a developing solution; and
(d) a step of bringing the solid phase including the resist film which has been subjected to development into contact with a nucleotide derivative having an acid-decomposable protective group.

2. The method for producing a nucleic acid array according to claim 1, wherein, after performing the step (a), the steps (b) to (d) are repeatedly performed a plurality of times.

3. The method for producing a nucleic acid array according to claim 2, wherein, after performing the step (a), the steps (b) to (d) are repeatedly performed four times while changing a type of nucleotide derivative each time.

4. The method for producing a nucleic acid array according to claim 3, wherein performing the step (a) and repeatedly performing the steps (b) to (d) four times while changing the type of nucleotide derivative each time are repeatedly performed any number of times.

5. The method for producing a nucleic acid array according to claim 1, wherein the step (a) includes subjecting the solid phase to hydrophobization treatment before forming the resist film.

6. The method for producing a nucleic acid array according to claim 1, wherein the step (c) includes irradiating the resist film with ultrasonic waves.

7. The method for producing a nucleic acid array according to claim 6, wherein a development time in the step (c) is 80 seconds or less.

8. The method for producing a nucleic acid array according to claim 1, wherein, after the step (b) and before the step (c), the resist film is not baked.

9. The method for producing a nucleic acid array according to claim 1, wherein the photo acid generator is selected from the group consisting of onium salts, diazomethanes, and sulfonic acid esters.

10. The method for producing a nucleic acid array according to any one of claims 1 to 9, wherein the acid-decomposable protective group is selected from the group consisting of acetyl groups (Ac), benzoyl groups (Bz), trityl groups (Tr), monomethoxyltrityl groups (MMT), dimethoxytrityl groups (DMT), trimethoxytrityl groups (TMT), β-methoxyethoxymethylether (MEM), methoxy methyl ether groups (MOM), tetrahydropyranyl groups (THP), and t-butyldimethylsilyl groups (TBS).

11. The nucleic acid array production device according to claim 1, wherein the positive resist composition is a novolac-based resist.

12. The nucleic acid array production device according to claim 1, wherein, after the step (c) and before the step (d), a step of cleaning the developed resist film is included.

13. A device for producing a nucleic acid array comprising:
a resist film formation part which is configured to form a resist film on a solid phase which has a molecule immobilized therein and has a functional group protected by an acid-decomposable protective group;
a light exposure part which is configured to expose a desired position of the resist film to light;
a development part which is configured to develop the resist film which has been exposed to light; and
a nucleotide derivative reaction part which is configured to bring the solid phase including the resist film which has been subjected to development into contact with a nucleotide derivative having an acid-decomposable protective group.

14. The device for producing a nucleic acid array according to claim 13, further comprising:
a solid phase moving part which is configured to move the solid phase between the resist film formation part, the light exposure part, and the development part; and
a solid phase moving controller which is configured to control the movement of the solid phase in the solid phase moving part.

15. The device for producing a nucleic acid array according to claim 13, wherein the light exposure part includes a light source, the light source is disposed above the resist film formation part, and all or a part of the resist film formation part is also used as the light exposure part.

16. The device for producing a nucleic acid array according to claim 13, wherein all or a part of the resist film formation part is also used as the development part.
